(19) United States
(12) Patent Application Publication
(10) Pub. No.: US 2025/0277867 A1
(43) Pub. Date: Sep. 4, 2025

(54) METHOD FOR MONITORING AN ENERGY STORAGE DEVICE IN A MOTOR VEHICLE

(71) Applicant: Robert Bosch GmbH, Stuttgart (DE)

(72) Inventors: Alexander Uwe Schmid, Budapest (HU); Philipp Schroeer, Althengstett (DE); Christel Sarfert, Korntal-Muenchingen (DE); Christoph Bolsinger, Stuttgart (DE)

(21) Appl. No.: 18/859,188

(22) PCT Filed: Jun. 27, 2023
(86) PCT No.: PCT/EP2023/067421

§ 371 Date: Oct. 23, 2024

(30) Foreign Application Priority Data
Aug. 5, 2022 (DE) 10 2022 208 191.9

(51) Int. Cl. G01R 31/392; B60R 16/033; G01R 31/382; G01R 31/389; G07C 5/08

(52) U.S. Cl. CPC G01R 31/392; B60R 16/033; G01R 31/382; G01R 31/389; G07C 5/0816

(57) ABSTRACT

A method for monitoring an energy storage device in a motor vehicle. The energy storage device supplies at least one in particular safety-relevant consumer, wherein at least one characteristic variable of the energy storage device describing the performance of the energy storage device is predicted, wherein at least one measured variable of the energy storage device is acquired and at least one state variable of the energy storage device is ascertained as a function of at least the measured variable, wherein the characteristic variable is predicted as a function of at least one state variable, wherein at least one aging of the energy storage device is ascertained by recording the current that has so far been drawn from the energy storage device, wherein the characteristic variable is ascertained as a function of the aging.

### FIELD

The present invention relates to a method for monitoring an energy storage device in a motor vehicle.

### BACKGROUND INFORMATION

German Patent DE 10 2019 219 427 A1 relates to a method for monitoring an energy storage device in a motor vehicle, wherein the energy storage device supplies at least one in particular safety-relevant consumer, preferably for an automated driving function, wherein at least one performance of the energy storage device is ascertained by predicting at least one characteristic variable of the energy storage device as a function of a load profile, wherein it is ascertained whether the energy storage device has been replaced and, if replacement of the energy storage device is identified, it is ascertained whether the replaced energy storage device is a permissible energy storage device.

An object of the present invention is to further increase the safety and reliability of a vehicle electrical system. The object may be achieved by certain features of the present invention.

### SUMMARY

According to an example embodiment of the present invention, ascertaining at least one aging of the energy storage device by recording the current that has so far been drawn from the energy storage device, wherein the characteristic variable is ascertained as a function of the aging variable, in particular makes it possible to identify the loss of active mass as a frequently occurring aging mechanism. Mapping the aging as an internal state variable in the method makes it possible to improve the accuracy of the prognosis. As a result, in particular safety-relevant consumers in the motor vehicle can be reliably supplied with energy, or countermeasures can be initiated in good time. The aging can be determined relatively easily.

In an expedient further development of the present invention, the characteristic variable is adjusted by adjusting the state variable as a function of the aging. These state variables are already used anyway in the prediction of the characteristic variable, so that a simple corresponding age-dependent correction enables a particularly easy and at the same time reliable adjustment.

In an expedient further development of the present invention, it is provided that the characteristic variable is ascertained using a specifiable load profile, in particular by taking into account a change in an operating point for determining the characteristic variable and/or a change in a discharge quantity defined by the load profile, as a function of the aging. The accuracy of the prediction is further increased specifically by taking into account the amount of charge of the load profile that leads to a change in the operating point. This is because the energy storage device discharges further due to the amount of charge removed, so that the resistance value on which the prediction of the characteristic variable is based continues to increase. This relationship is accordingly taken into account.

In an expedient further development of the present invention, it is provided that the aging is determined using the current that has so far been drawn from the energy storage device by ascertaining a current-time throughput and/or by ascertaining an integral of the current drawn from the energy storage device and/or by ascertaining a cumulative current-time throughput, preferably amp-hour throughput, over the lifetime of the energy storage device. Thus, particularly simple method steps can be used to determine the aging.

In an expedient further development of the present invention, it is provided that the aging is continuously updated and the updated aging is used to ascertain the characteristic variable. This makes it possible to predict the performance of the energy storage device in every situation of the vehicle, which further increases safety. This approach stipulates that the degree of aging due to the loss of active mass correlates with the cumulative current throughput of the energy storage device, i.e. the total current throughput over the lifetime of the energy storage device.

In an expedient further development of the present invention, the aging is ascertained by relating the current-time throughput drawn so far to a parameter that depends on the energy storage device, in particular a maximum charge that can be drawn from the energy storage device. This enables a particularly simple scaling in relation to a new energy storage device using the thus ascertained aging. This simplifies the further method steps.

In an expedient further development of the present invention, the characteristic variable is ascertained as a function of the predicted resistance, in particular the internal resistance, of the energy storage device using a load profile. The resistance can be used to easily map the influence of aging one the state variables. Particularly expediently provided here is a state correction that corrects at least the state variable of the energy storage device, in particular an open-circuit voltage and/or in particular a state of charge, as a function of the aging using a curve that describes the relationship between the state variable, in particular the open-circuit voltage or in particular the state of charge, and the resistance, in particular the internal resistance, of the energy storage device. This enables a particularly simple but precise correction of the relevant variables as a function of the aging. It is particularly expediently provided here that the curve is described as a function of a state variable, in particular an open-circuit voltage, and the compression of the curve is carried out using the corrected state variable, in particular by multiplying the aging by a function value.

In an expedient further development of the present invention a charge correction is provided, which ascertains a corrected charge as a function of the aging and the corrected charge ascertained from the charge correction is used for the prediction of at least one state variable or performance prognosis. This can improve the accuracy of the prognosis for other prognosis types as well.

Other expedient further developments of the present invention will emerge from the disclosure herein.

### BRIEF DESCRIPTION OF THE DRAWINGS

FIG. 1 shows a possible vehicle electrical system for a vehicle with a safety-relevant consumer, according to an example embodiment of the present invention.

FIG. 2 shows a schematic illustration of the various blocks used in the method, according to an example embodiment of the present invention.

FIG. 3 shows an example of the effect of aging on the open-circuit voltage of the energy storage device as a function of the state of charge.

FIG. 4 shows an example of compression of the resistance-open-circuit voltage curve or the resistance-state of charge curve due to aging on the energy storage device.

FIG. 5 shows a correction of the input value, in particular the open-circuit voltage, based on the compression of the resistance-input variable curve due to aging on the energy storage device.

FIG. 6 shows the correction of the input value according to FIG. 5 in a different illustration.

FIG. 7 shows an illustration of a compression of the resistance-open-circuit voltage curve to ascertain the changed resistance due to aging on the energy storage device.

FIG. 8 shows an illustration of a compression of the resistance-state of charge curve to ascertain the changed resistance due to aging on the energy storage device.

FIG. 9 shows a determination of the resistance of the energy storage device (for example the internal resistance) as a function of the open-circuit voltage or the state of charge for a new energy storage device and an aged energy storage device with the operating point shifted by the charge removal.

FIG. 10 shows an increased load on the energy storage device due to aging, expressed as the amount of charge in relation to the remaining energy storage capacity.

### DETAILED DESCRIPTION OF EXAMPLE EMBODIMENTS

The present invention is illustrated schematically in the drawings on the basis of embodiments and is described in detail in the following with reference to the figures.

A battery or accumulator is described in the embodiment example as an example of a possible energy storage device. However, other energy storage devices suitable for this task, for example on an inductive or capacitive basis, fuel cells, capacitors, or the like, can alternatively be used as well.

FIG. 1 shows a possible topology of an energy supply system consisting of a basic vehicle electrical system 22 that supplies at least one basic consumer 24, which is shown as an example. An energy storage device or a battery with an associated (battery) sensor and/or a starter, and/or several non-safety-relevant comfort consumers, which could be protected or controlled by an electrical load distribution, could alternatively also be provided in the basic vehicle electrical system 22. The basic vehicle electrical system 22 has a lower voltage level than a high-voltage vehicle electrical system 10; it can, for instance, be a 12 V vehicle electrical system. A DC voltage converter 20 is disposed between the basic vehicle electrical system 22 and the high-voltage vehicle electrical system 10. The high-voltage vehicle electrical system 10, for instance, comprises a high-voltage energy storage device 16, such as a high-voltage battery, possibly with an integrated battery management system (shown as an example is a non-safety-relevant load 18 or comfort consumer such as an air-conditioning system supplied with an increased voltage level, etc.) and an electric machine 12. The energy storage device 16 can be connected via a switching means (switch) 14 to supply the high-voltage vehicle electrical system 10. High-voltage in this context is understood to mean a voltage level that is higher than the voltage level of the basic vehicle electrical system 22. It could be a 48-volt vehicle electrical system, for example. Especially in vehicles with an electric drive, it could alternatively be an even higher voltage level. The high-voltage vehicle electrical system 10 could alternatively be eliminated entirely; in which case components such as the starter, the generator and the energy storage device are assigned to the basic vehicle electrical system 22.

Two safety-relevant channels 30, 40 are connected to the basic vehicle electrical system 22, for example. The first safety-relevant channel 30 is connected to the basic vehicle electrical system 22 via a separating element 28. The other safety-relevant channel 40 is connected to the basic vehicle electrical system 22 via a further separating element 26. The first safety-relevant channel 30 can be supplied with energy via an energy storage device 32. The characteristic variables of the energy storage device 32 are acquired by a sensor 34. The sensor 34 is preferably disposed adjacent to the energy storage device 32. The first safety-relevant channel 30 supplies a safety-relevant consumer 36. This safety-relevant consumer 36 is only shown as an example. Further safety-relevant consumers 36 are supplied via the safety-relevant channel 30 as needed.

The further safety-relevant channel 40 can also be supplied by a further energy storage device 42. The characteristic variables of the further energy storage device 42 are acquired by a further sensor 44. The further sensor 44 is disposed adjacent to the further energy storage device 42. The further safety-relevant channel 40 supplies at least one further safety-relevant consumer 46. Other safety-relevant consumers 46 can also be supplied in the further safety-relevant channel 40 as needed.

The topology shown in FIG. 1 is selected merely as an example of one of many embodiment examples. There are a variety of ways in which the safety-relevant channels 30, 40 are mounted. For instance, it would be possible for the further safety-relevant channel 40 to be attached to the safety-relevant channel 30 or to the channel 10 via a further DC voltage converter. Alternatively, only a single channel 30, 40 with only one energy storage device 32 could be provided.

The separating element 26, 28 serves to secure the respective safety-relevant channels 30, 40 so that any errors occurring in the basic vehicle electrical system 22 and/or in a safety-relevant channel 30, 40 cannot affect the other safety-relevant channel 30, 40. This may involve appropriate switching means or DC voltage converters via which a separation or connection of the subsystems becomes possible. The separating elements 26, 28 could alternatively be eliminated entirely so that the channels 30, 40 are connected directly to the DC voltage converter 20.

The redundant, in particular functionally redundant, safety-relevant consumers 36, 46 that can be supplied via the two safety-relevant channels 30, 40 are those that are necessary to transfer a vehicle from an automated driving mode (no driver intervention required) to a safe state, for example in the event of a critical error. This can involve stopping the vehicle, be it immediately, on the side of the road, or at the nearest rest stop, etc.

The functionality of the energy storage device 16, 32, 42 to supply the safety-relevant consumer(s) 36 nonetheless plays an important part, even in the event of a possible error. With the introduction of electric steering and brakes and the increasing automation of the vehicle, it is becoming more and more important to ensure reliable electrical supply of these safety-relevant components or consumers 36, 46. Since the energy storage device 16, 32, 42 plays a key role in this, the functions that now have to determine the performance of the energy storage device 16, 32, 42 have to be developed in accordance with particularly stringent requirements, such as those laid down in ISO 26262. This also has far-reaching consequences for the development of functions and algorithms, and for the hardware on which these functions are used. The method discussed in the following enables a reliable prediction of a characteristic variable, such as the voltage Up of the energy storage device 16, 32, 42 in accordance with ISO 26262. The prediction of the characteristic variable Up which describes the performance of the energy storage device 32 is an essential component for a vehicle electrical system 30, 40 that is safe in accordance with safety standards.

When predicting the performance in the context of reliably supplying safety-relevant consumers 36, 46, until the vehicle is in a safe state (the vehicle is parked safely on the side of the road, in a parking lot, etc.), it is important to ensure that the energy storage device 16, 32, 42 can operate at least one or more safety-relevant consumers 36, 46, as is the case with a superimposed steering and braking process.

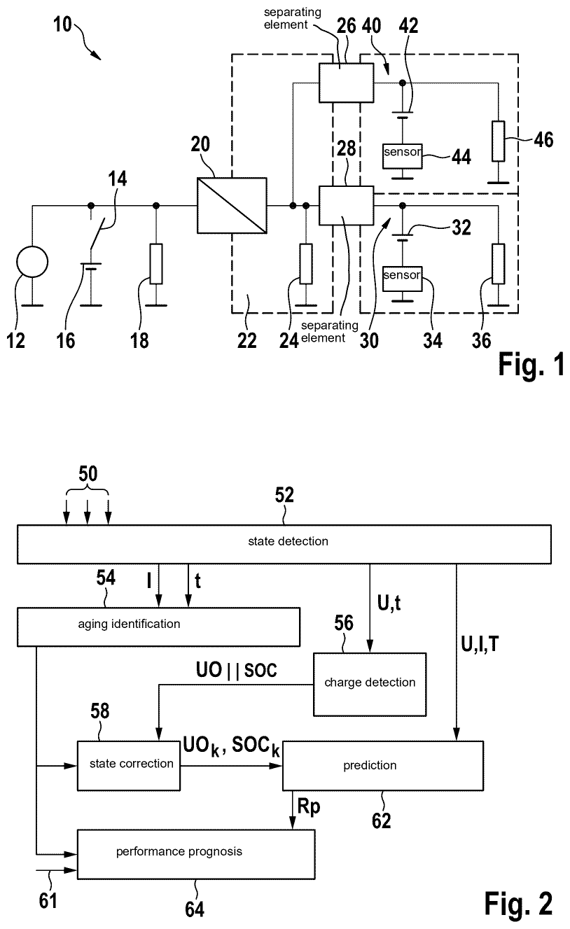

The embodiment example according to FIG. 2 shows a schematic illustration of the method. A variety of measurement data 50, for example ascertained by the sensor 34, 44, are sent to a state detection 52 of the energy storage device 32. The state detection 52 ascertains specific (state) variables of the energy storage device 32 and passes them on as appropriate. At least one current I drawn from the energy storage device 32 and associated time information t for ascertaining the current profile I(t) are sent to an aging identification 54. The aging identification 54 ascertains an aging x of the energy storage device 32. The aging x is particularly preferably a loss of active mass of a battery as a possible energy storage device 32. The aging x is sent to a state correction 58. A state of charge detection 56 is provided as well, to which at least the voltage U and/or the time t or the time profile is provided by the state detection 52. The state of charge detection 56 ascertains at least one open-circuit voltage U0 of the energy storage device 32 and/or at least one state of charge SOC of the energy storage device 32 as possible state variables, for example. The open-circuit voltage U0 and/or the state of charge SOC are sent to the state correction 58 as well. The state correction 58 ascertains at least one corrected open-circuit voltage U0k and/or a corrected state of charge SOCk. The corrected open-circuit voltage U0k and/or the corrected state of charge SOCk are sent to a prediction 62 for a predicted resistance Rp of the energy storage device 32. The prediction 62 for the predicted resistance Rp is also provided with the voltage U and/or the current I and/or the temperature T as provided by the state detection 52.

A performance prognosis 64 is provided as well. At least the aging x as ascertained by the aging identification 54 and/or the predicted resistance Rp as ascertained by the prediction 62 and/or the load profile 61 are fed to the performance prognosis 64. The performance prognosis 64 ascertains a characteristic variable for the performance of the energy storage device 32, for example the predicted voltage Up that occurs after the load profile 61 is applied to the energy storage device 32.

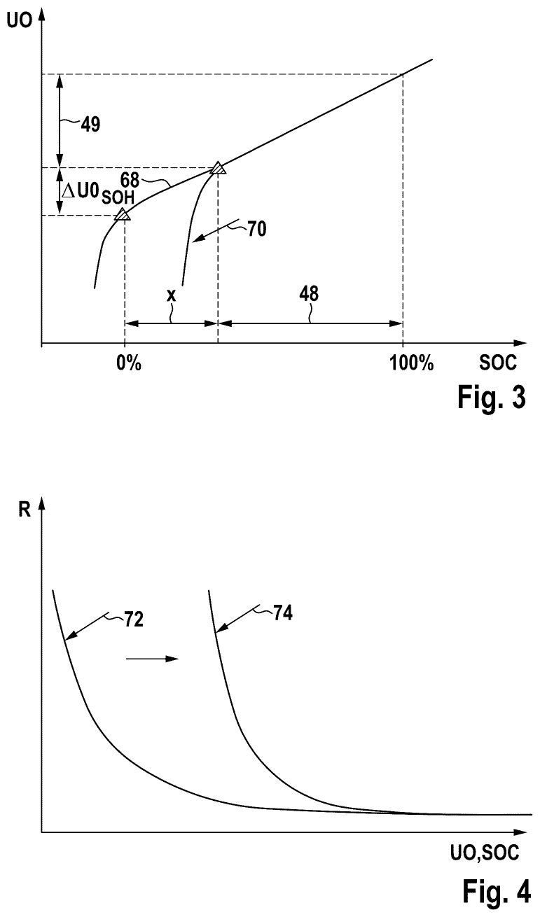

FIG. 3 shows the physical effect of the loss of active mass (LAM) as the possible aging x on the relationship between the open-circuit voltage U0 and the state of charge SOC of the energy storage device 32. The curve 68 shows the progression of the open-circuit voltage U0 as a function of the state of charge SOC at the begin of life (BOL) of the energy storage device 32. This curve 68 is characterized by the fact that sufficient open-circuit voltages U0 can be achieved even at low states of charge SOC as indicated by the first point on the curve 68. At this point, the open-circuit voltage U0bol (open-circuit voltage U0 at the begin of life (BOL)) is assigned at the state of charge SOC 0% at the begin of life. The curve 70 describes the progression of the open-circuit voltage U0 for an energy storage device 32 aged by the aging x. This progression of the curve 70 is characterized by the fact that the open-circuit voltage U0 already collapses at higher states of charge SOC before the two curves 68, 70 approach or merge into one another at the other shown point. This corresponding voltage swing ΔU0soh of the open-circuit voltage U0 in relation to the aging x between these two points is shown as an example in FIG. 3. For an energy storage device 32 aged in accordance with the curve 70, this results in a permissible range 48 for the state of charge SOC and another permissible range 49 for the open-circuit voltage U0. The permissible range 49 for the open-circuit voltage U0 is above the voltage swing ΔU0soh in relation to the open-circuit voltage U0bol.

FIG. 4 shows the physical effect of the loss of active mass on the resistance R of the energy storage device 32. This shows an example of a compression of the resistance-state variable characteristic curve (R(U0), R(SOC) the open-circuit voltage U0 or the state of charge SOC as possible state variables) for a new energy storage device 32 (curve 72 at the begin of life BOL) of the energy storage device 32) and for an aged energy storage device 32 (curve 74 of the aged energy storage device 32) due to aging x, in particular loss of active mass. The curves 72, 74 have a monotonically decreasing progression which approaches a constant resistance value R with increasing state variables U0, SOC. The curve 74 of an aged energy storage device 32 rises in the direction of lower states of charge earlier than the curve 74 of a new energy storage device 32. In the case of the curve 72 at the begin of life BOL of the energy storage device 32, a respective resistance R (for example the internal resistance Ri of the energy storage device 32) is reached at a lower open-circuit voltage U0 or a lower state of charge SOC, whereas, in an aged energy storage device 32, the same resistance R occurs already at a higher open-circuit voltage U0 or a higher state of charge SOC. A corresponding compression of the curve 72 in the direction of the curve 74 is taken into account for the performance prediction 64 of the energy storage device 32 via the state correction 58 as described in the following.

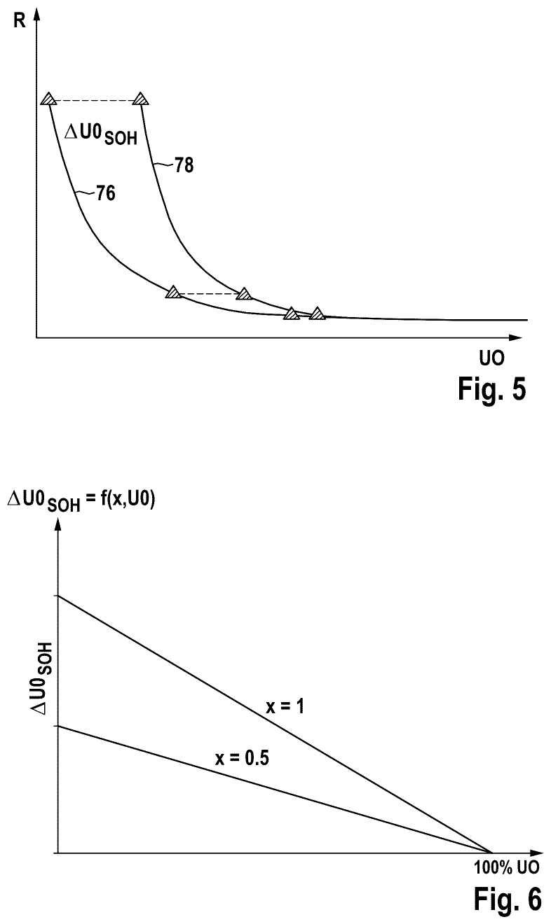

FIG. 5 shows the compression of a resistance curve via a correction of the state variable or the input value, in particular the open-circuit voltage, due to the aging x on the energy storage device 32. As the open-circuit voltage U0 increases, the difference in the voltage swing ΔU0soh of the open-circuit voltage U0 for a new (curve 76) and an aged (curve 78) energy storage device 32 decreases.

FIG. 6 shows the correction of the input value according to FIG. 5 in another illustration. The associated voltage swing ΔU0soh of the open-circuit voltage U0 is shown as a function of the open-circuit voltage U0 and the aging x. The respective agings x (x=0.5, x=1 are shown as an example) result in falling straight lines that intersect at U0=100%.

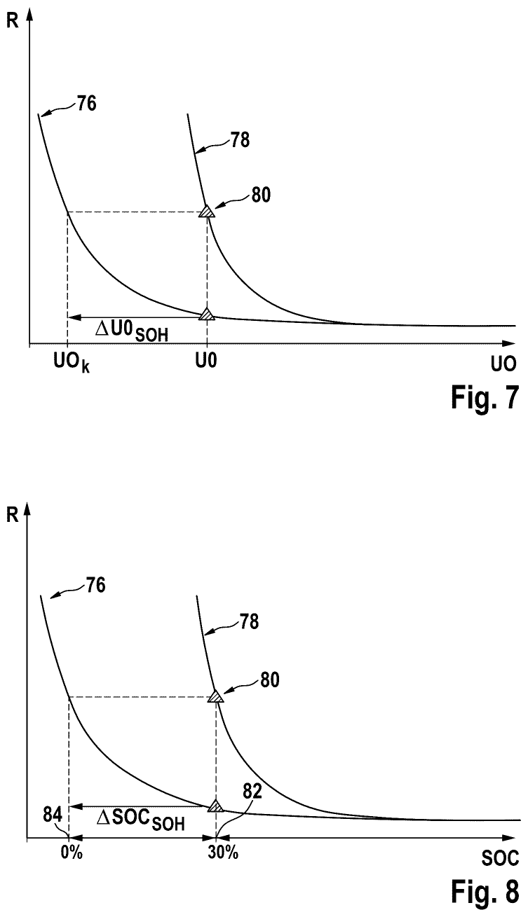

FIG. 7 shows the principle of compressing the resistance-open-circuit voltage curve to ascertain the changed resistance R due to the aging x on the energy storage device 32, wherein the aged curve 78 can be transferred to the curve 76 by the correction term. FIG. 8 similarly shows an illustration of a compression of the resistance-state of charge curve to ascertain the changed resistance R due to the aging x on the energy storage device 32.

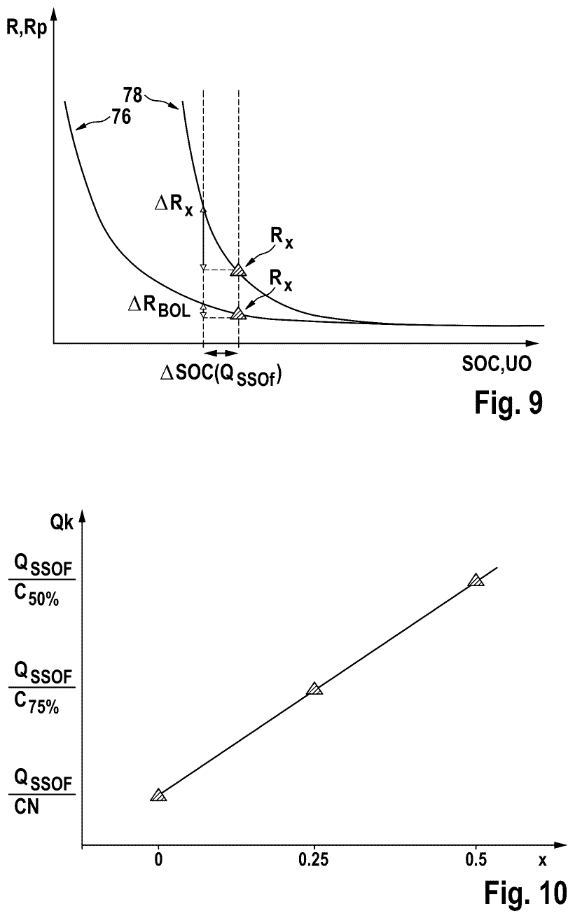

FIG. 9 shows the determination of the resistance R (for example the internal resistance Ri) of the energy storage device 32 as a function of the open-circuit voltage U0 or the state of charge SOC for a new energy storage device 32 (curve 76) and the determination of the resistance R of an aged energy storage device 32 as a function of the open-circuit voltage U0 or the state of charge SOC (curve 78). An adaptive follow-up control is carried out using state correction 58 via the corrected open-circuit voltage U0k or the state of charge SOCk as the corrected state variable. The charge Qssof removed by the load profile 61 serves as an input variable for the prognosis of the resistance R as well.

FIG. 10 shows an increased load on the energy storage device 32 due to the loss of active mass, expressed as the amount of charge Qssof needed to apply the load profile 61 to the energy storage device 32, in relation to the remaining capacity (Cx). In the example C75%, 75% of the remaining capacity of the energy storage device 32 remains due to aging as a result of the 25% loss of active mass. Other aging factors are not taken into account in FIG. 5. The greater load on the battery is taken into account in a charge correction via the corrected amount of charge Qk.

The problem and the corresponding blocks of FIG. 2 are described in more detail in the following.

Next to corrosion, loss of active mass (LAM) is a frequently occurring aging x, in particular in electrochemical energy storage device 32 (lead-acid batteries, lithium-ion cells). Reducing the active electrochemical reaction surface increases the cell impedance. Aging mechanisms are moreover usually superimposed, i.e. multiple mechanisms in different forms occur at the same time. Often, only limited electrical characteristics of the energy storage device 32 (current I, voltage U, temperature T) are known via measurement data 50 (for example acquired by the sensors 34, 44) in the vehicle. Identifying the loss of active mass as a particularly important aging x during vehicle operation is challenging. To enable the most accurate possible but nonetheless reliable performance prognosis of energy storage devices 32, in particular for safety-relevant applications in the vehicle over the entire lifetime, the aging x (loss of active mass (LAM (state of health=100%−LAM)) of the energy storage device 32 has to be identified and taken into account continuously. Mapping the aging x, in particular the loss of active mass, as an internal state variable in the method makes it possible to improve the accuracy of the prognosis.

When predicting the performance in the context of reliably supplying safety-relevant consumers 36, 46, until the vehicle is in a safe state (the vehicle is parked safely on the side of the road, in a parking lot or the like), it is important to ensure that the energy storage device 32 can supply the consumer 36, 46. For functionality in the safety-relevant context, this requires the method to recognize multifactorial relationships for all possible operating scenarios and weight them accordingly. A reliable prognosis or prediction of the voltage Up of the energy storage device 32 as the characteristic variable Up that describes the performance of the energy storage device 32 is always needed. The aging x has to therefore be sufficiently taken into account.

For this purpose, a quantitative determination of the aging x, in particular the loss of active mass LAM (for example, in the case of lead-acid batteries) based on the amp-hour throughput (Ah) is proposed. The approach stipulates that the degree of loss of active mass LAM as aging x correlates with the cumulative amp-hour throughput of the energy storage device 32, in particular the total amp-hour throughput over the lifetime of the energy storage device. Once a limit value has been reached, switching off the function ensures that no incorrect prognoses are made.

The minimum quality requirements for energy storage devices 32 with respect to cyclic loading are usually specified by the manufacturer. An amp-hour counter for ascertaining the aging x can be expressed relative to the maximum permitted amount of charge Qmax. The cumulative amounts of charge of the energy storage device 32 can be weighted differently depending on the ambient conditions. The final value of the amp-hour counter as a measure of the aging x is used as an input variable for the performance prognosis 64. The predicted voltage drop at the begin of life is scaled in accordance with the current aging x.

Of particular importance is a determination of the current state of charge SOC or the open-circuit voltage U0 of the energy storage device 32 as provided by the state of charge detection 56 as possible state variables. The operating range with respect to the state of charge SOC is restricted by the aging x, specifically the loss of active mass LAM. As shown in FIG. 3 by the curve 70 (for example 40% LAM), the usable discharge quantity of the energy storage device 32 decreases as the aging x increases because the deep states of charge SOC can no longer be achieved (for example, between 0% and 40%). Due to the loss of active mass in the energy storage device 32, there is a lack of reaction partners for the conversion of the sulfuric acid, for example in a lead-acid battery. As a result of the shortage of reaction partners, the voltage drop in the lower state of charge range SOC increases.

This effect of the loss of active mass as a corresponding aging x on the open-circuit voltage U0 and the state of charge SOC of the energy storage device 32 is shown as an example in FIG. 3. In order to be able to determine the age-dependent voltage drop via the portion of the loss of active mass or aging x (see FIG. 4), the usable capacity range of the energy storage device 32 (see FIG. 3) is described via the corrected open-circuit voltage U0k or the corrected state of charge SOCk. The presented concept takes these age-dependent changes into account with the following implementations:
(1) The operating point is changed by the current load pulse (SSOF requirement expressed as amount of charge) or the associated load profile 61 as a result of a reduced operating range (U0 or SOC)
   a. Shifting stored resistance or voltage drop characteristic curves (compression of the operating range) by correcting the input value or the state variable (e.g. U0, SOC). The SSOF function or Block 64 can be temporarily deactivated if the state of charge SOC is lower than the loss of active mass LAM or the aging x (see FIG. 3).
   b. For performance prognosis models (performance prognosis 64) with a charge and discharge history: taking into account the increased effective amount of charge Q due to the decreased capacity C of the energy storage device 32 (see FIG. 10).
   c. In a performance prognosis model with a resistance determination: predicting the resistance Rp: changing the resistance R based on the changed operating point ΔR (ΔSOCssof). The change in the operating point due to the charge conversion of the SOF pulse ΔSOCssof changes the resistance R of the energy storage device 32 by ΔR (see FIG. 9): Rp=Rx+ΔRx. An additional limitation of the permitted change in the operating point of the resistance R can be achieved via a threshold value.
(2) Alternatively, the prognostic value, for instance expressed as a polynomial function, can be adjusted using parameters that are dependent on the aging x (without correcting the state variables SOC or U0).

### Aging Identification 54 to Ascertain the Aging x

The calculated current value of the counter (e.g. the amp-hour throughput counter; the current integral of the current I that has so far been drawn from the energy storage device 32, etc.) is normalized to the maximum permitted or achievable value Qmax (maximum amp-hour throughput) of the energy storage device 32 used under standard conditions. The performance prognosis 64 is adjusted in the range between 0 (no aging x (begin of life BOL or production of the energy storage device 32)) and 1 (maximum aging x: end of life EOL). As a simple type of implementation, the amp-hour throughput can be ascertained via a current integration. The current measurement value I as ascertained by the sensor 34, 44 could be used here and integrated (taking into account the time t (duration t of the current flow I) as provided by the state detection 52, for example), from which the actual amp-hour throughput Qt is determined. The maximum amp-hour throughput Qmax is determined from cyclic tests of the respective energy storage device 32, for instance. The aging x is determined from the quotient of the actual amp-hour throughput Qt and the maximum amp-hour throughput Qmax for the respective energy storage device 32:

$$Aging x = Qt / Q max$$

so that values between 0 and 1 result for the aging x. Qmax is often set such that the end of life target, e.g. 50% LAM or aging x=50% for lead-acid batteries, is achieved.

The measured voltage U on the energy storage device 32 can potentially also be used to ascertain the aging x.

### State Correction 58

Due to the compression of the operating range as a result of loss of active mass in the lower U0 or SOC range, a scaling that is dependent on the input value U0 or SOC is introduced in order to be able to describe the drift of the characteristic variable.

The open-circuit voltage U0k is corrected via the voltage change ΔU0soh for an aged energy storage device 32 (see also FIG. 3):

$$U 0 k = U 0 - Δ U 0 soh$$

wherein ΔU0soh is a function of the LAM or the aging x or the LAM (from the aging identification 54) and the input value is U0.

$$Δ U 0 soh = f ( LAM or x , U 0 )$$

The aging term is used in the aging identification 54:

$$x = aging = Qt / Q max$$

wherein x=0 (begin of life BOL) and x=1 (end of life EOL)

The procedure is shown as an example in FIGS. 5 and 6. The input value of the open-circuit voltage U0 is thus corrected by ΔU0soh (corrected open-circuit voltage U0k). The state of charge SOC input value can be corrected in the same way (corrected state of charge SOCk). The correction term depends on the current aging x and the value of the input value U0 or SOC. As can be seen in FIGS. 5 and 6, a higher input value has to be corrected less than an input value in the lower range.

The following example illustrates the described relationships. The battery has the following data: 0% SOCbol: U0min=11.6 V; 100% SOCbol: U0max=13 V. The aging x or the LAM, as provided by the aging identification 54, is determined to be 30%, for instance. With x=Qt/Qmax=30%/50% (with EOL criterion or Qmax is 50% LAM)=0.6. The available range 48 of the state of charge SOCbol is between 30% and 100%. The available range 49 of the open-circuit voltage U0 is therefore between 12 and 13 V. As an example, an open-circuit voltage U0 of 12.15 V is measured. This corresponds to approximately 40% of the state of charge SOCbol at the begin of life (BOL) of the energy storage device 32. With maximum aging x=1, U0 decreases by (U0max−U0min)*50%=0.7 V (see FIG. 5).

With U0=12.15 V or SOCbol=40% state of charge, the correction term is ΔU0soh, 1=f(U0)=(U0max−U0min, cor)/100%*40%=1 V/100%*40%=0.4 V.

With x=6, ΔU0soh=0.4 V*0.6=0.24 V (see FIG. 6).

Taking into account the correction term ΔU0soh of the aged energy storage device 32, the corrected open-circuit voltage U0k is then (see FIG. 7):
U0k=U0−ΔU0soh=11.718 V. (U0k: corrected state variable, for example the open-circuit voltage)

### Block 62 for Predicting the Resistance Rp

Taking into account the corrected input value or state variable U0k, SOCk, the resistance R of the energy storage device 32 changed by the loss of active mass (determined via the aging x) can be determined. An example compression of the resistance input value curve or resistance-state variable curve due to the loss of active mass of the energy storage device 32 is shown in FIG. 7, for example, as a function of the open-circuit voltage U0 and in FIG. 8 as a function of the state of charge SOC.

The value U0 shown in FIG. 7 represents the initially determined value from the state of charge detection 56. This is accordingly corrected as described above by the change in the open-circuit voltage ΔU0soh for an aged energy storage device 32 to obtain the corrected value U0k (as indicated in FIG. 7 with the arrow). The so-called true value 80 of the resistance R (as shown in the aging x shifted curve 78) can in principle be taken from the aging-shifted characteristic curve 78. However, the curve 76 is stored as a parameterized function for a new energy storage device 32 (BOL), for example, so that the associated resistance R is ascertained via the corrected open-circuit voltage value U0k in conjunction with the open-circuit voltage value 76.

The same applies to the state of charge SOC as the input variable as shown in FIG. 8. The SOC value 82 (SOC value for a new energy storage device 32) of 30% initially determined by the state of charge detection 54 is accordingly corrected by the aging x or by ΔSOCsoh, value 84 (SOC value for an aged energy storage device 32). The true value 80 of the resistance R can in principle be taken from the aging-shifted characteristic curve 78. However, the curve 76 is stored as a parameterized function, for example, so that the associated resistance R is ascertained via the corrected state of charge value SOCk in conjunction with the curve 76.

FIG. 9 already shows the determination or prediction of the resistance Rp (for example the internal resistance Ri of the energy storage device 32) as a function of the open-circuit voltage U0 or the state of charge SOC for a new energy storage device 32 (curve 76) and for an aged energy storage device 32 (curve 78 for the respective constantly changing aging x).

The resistance Rp (for example the internal resistance Ri of the energy storage device) is determined via the input variables or the state variables open-circuit voltage U0 or state of charge SOC for a new energy storage device 32 (curve 76) and an aged energy storage device 32 (curve 78) using the state values U0k, SOCk corrected by the state correction 58.

Taking into account the amount of charge Qssof of the load profile 61 (SOF profile), which must still be able to be applied to the energy storage device 32, leads to a change in the operating point ΔU0(Qssof) or ΔSOC(Qssof) which is included in Block 62. Qssof (additional charge removal due to the load profile 61 in FIG. 9) also serves as the input parameter for the prognosis of the resistance value Rp after the occurrence of the current pulse SOF or after the occurrence of the load profile 61 (worst case prognosis). The resistance Rp is determined at the end of the current pulse (SOF profile or load profile 61, for example in the form of a specifiable current profile with a specific height and duration), because the energy storage device 32 is further discharged by the amount of charge Qssof drawn in conjunction with the load profile 61 (with the resulting change in the open-circuit voltage ΔU0(Qssof) or the changed state of charge ΔSOC(Qssof)) and allows the resistance value R to increase by ΔR. A shift of the operating point due to the further charge removal Qssof, resulting from the application of the load profile 61, leads to a further change in the state variables U0, SOC (by ΔU0(Qssof) or ΔSOC(Qssof)). The changes in the state variables U0, SOC result in a changed resistance value ΔR (ΔRbol for a new energy storage device 32, corresponding to the curve 76 or, by a larger value ΔRx for an aged energy storage device 32, curve 78). The resistance value ΔRx, which is similarly changed by the operating point shift, is taken into account in the subsequent ascertainment of the characteristic variable Up which describes the performance of the energy storage device 32.

The compression of the resistance curve of the energy storage device 32 (R-U0 curve) can be implemented in a variety of ways. One way is to map a polynomial function, wherein an age-dependent factor x adjusts the function via the proportion of loss of active mass. A correction of the state variables U0 or SOC would then not be necessary.

### Performance Prognosis 64 (SSOF Prognosis)

The adapted resistance value Rp or the predicted resistance value Rp in Block 62 can be used as the input variable for the performance prognosis 64 (see FIG. 2). This can be converted to the predicted voltage drop Up on the energy storage device 32 using the current or load requirements (for example also multiple load profiles 61, etc.). Lastly, using the estimated (uncorrected) open-circuit voltage U0, the prognostic value Up can be determined as the characteristic variable describing the performance of the energy storage device 32.

Example:

$$Ussof = Up = U 0 - Δ UR$$

$$With Δ UR = Issof * R$$

(with Issof as the associated current profile of the load profile 61, R the resistance Rp predicted in Block 62 (taking into account the corrected state variables U0k, SOCk) and taking into account the operating point changes caused by the load profile 61 and the resulting change in resistance by ΔRx).

An alternative or additional way of incorporating the aging x into the SSOF prediction or performance prognosis 64 is scaling the prognostic value:

$$Δ UR = f ( x ) = Issof * R * ( 1 + LRM ) = Issof * R ( 1 + x )$$

wherein LAM as the loss of active mass or measure of the aging x is determined via the aging identification 54.

In general, a specific load profile 61, for example a current profile with defined lengths of time, can be used as the basis for predicting the performance or a characteristic variable Up of the energy storage device 32. The prediction could, for instance, be made as a function of the open-circuit voltage U0 and/or the voltage drop at the predicted internal resistance Ri using a specific load profile 61. The values corrected in conjunction with the aging x can then be used as described above.

In the case of performance prognoses with a charge/discharge history, the increased amount of charge can be taken into account. The reduction of the available capacity C due to loss of active mass or aging x increases the influence of the amount of charge Q on the behavior of the energy storage device 32. The factor Q/Ct (Ct: actual capacity of the energy storage device 32) indicates the amount of charge Q adjusted to the current capacity Ct of the energy storage device 32. For example, for SOH=0% or aging x=1 (with end of life definition 50% capacity loss) the corrected charge Qk is:

$$Qk = Q / C 50 \% * C 100 \% = 2 * Q$$

wherein Cn is the nominal capacity of the energy storage device 32. The respective relationships of the increased load on the energy storage device 32 as a result of loss of active mass, expressed as the amount of charge Q in relation to the remaining capacity C of the energy storage device 32, are shown in FIG. 10. With C 75%, 75% of the remaining capacity of an energy storage device 32 is assigned due to aging x as a result of 25% loss of active mass; other aging factors are not taken into account.

If the actual functionality of the energy storage device 32 is not achieved, countermeasures are initiated. A warning is issued, for instance, and/or safety-relevant functions are blocked. The warning can be shown to the driver on a display or other display means. A corresponding warning could alternatively also be displayed via suitable communication channels, for example to the workshop, a fleet operator, etc. The manual or automatic transition of the vehicle to a safe state, such as stopping on the side of the road, driving to the next parking lot or the like (so-called safe stop of the vehicle), could be initiated as well.

The described method is particularly suitable for monitoring energy storage devices 16, 32, 42 for safety-relevant applications, for example for supplying safety-relevant consumers in a motor vehicle, in particular during autonomous or semi-autonomous driving. However, use is not limited to this.

1-15. (canceled)

16. A method for monitoring an energy storage device in a motor vehicle, wherein the energy storage device supplies at least one safety-relevant consume, the method comprising:
predicting at least one characteristic variable of the energy storage device describing performance of the energy storage device;
acquiring at least one measured variable of the energy storage device;
ascertaining at least one state variable of the energy storage device as a function of at least the measured variable, wherein the characteristic variable is predicted as a function of at least the state variable;
ascertaining at least one aging of the energy storage device at least by recording current that has so far been drawn from the energy storage device, wherein the characteristic variable is predicted as a function of the aging.

17. The method according to claim 16, wherein the characteristic variable is adjusted by adjusting the state variable as a function of the aging.

18. The method according to claim 16, wherein a performance prognosis is provided, which ascertains the characteristic variable using a specifiable load profile, by taking into account a change in an operating point for determining the characteristic variable and/or a change in a discharge quantity defined by the load profile as a function of the aging.

19. The method according to claim 16, wherein the aging is determined using the current that has so far been drawn from the energy storage device by ascertaining a current-time throughput and/or by ascertaining an integral of the current drawn from the energy storage device and/or by ascertaining a cumulative current-time throughput over the lifetime of the energy storage device.

20. The method according to claim 16, wherein the aging is continuously updated and the updated aging is used to ascertain the characteristic variable.

21. The method according to claim 16, wherein the aging is ascertained by relating the current-time throughput drawn so far to a parameter that depends on the energy storage device, including a maximum charge that can be drawn from the energy storage device.

22. The method according to claim 16, wherein the characteristic variable is ascertained as a function of a predicted resistance, including an internal resistance of the energy storage device using a load profile.

23. The method according to claim 16, wherein a state correction corrects at least the state variable of the energy storage device, including an open-circuit voltage and/or a state of charge, as a function of the aging using a curve that describes a relationship between: (i) the state variable, including the open-circuit voltage and/or the state of charge, and (ii) and internal resistance of the energy storage device.

24. The method according to claim 23, wherein the curve is described as a function of a state variable, and a compression of the curve is carried out using a corrected state variable, by multiplying the aging by a function value.

25. The method according to claim 16, wherein a state of charge detection is provided, which ascertains at least one state variable describing a state of charge of the energy storage device including an open-circuit voltage and/or a state of charge.

26. The method according to claim 16, wherein a charge correction is provided, which ascertains a corrected charge as a function of the aging and the corrected charge ascertained from the charge correction is used for the prediction of at least one state variable or performance prognosis.

27. The method according to claim 16, wherein the aging is ascertained, the state variable is corrected as a function of the aging, a resistance of the energy storage device is ascertained as a function of the corrected state variable by using a curve at a beginning of the life of the energy storage device that describes the relationship between the state variable and the resistance to infer a characteristic variable of the energy storage device at a current aging.

28. The method according to claim 16, wherein, when the predicted characteristic variable reaches a limit value, a measure is initiated including blocking a safety-relevant function and/or outputting a warning.

29. The method according to claim 16, wherein, when a limit value of an aging function is reached or a lower limit value of the state variable is reached due to a changed operating point, a measure is initiated including a temporarily blocking of a safety-relevant function and/or outputting a warning.

30. An apparatus configured to monitoring an energy storage device in a motor vehicle, wherein the energy storage device supplies at least one safety-relevant consumer, the apparatus comprising:
at least a state detection and/or aging identification and/or at least a state of charge detection and/or at least a state correction and/or a prediction of a resistance of the energy storage device and/or at least a performance prognosis;
wherein the apparatus is configured to:
predict at least one characteristic variable of the energy storage device describing performance of the energy storage device,
acquire at least one measured variable of the energy storage device,
ascertain at least one state variable of the energy storage device as a function of at least the measured variable, wherein the characteristic variable is predicted as a function of at least the state variable,
ascertain at least one aging of the energy storage device at least by recording current that has so far been drawn from the energy storage device, wherein the characteristic variable is predicted as a function of the aging.
